(19) United States
(12) Patent Application Publication
(10) Pub. No.: US 2013/0060493 A1
(43) Pub. Date: Mar. 7, 2013

(54) SYSTEMS AND METHODS FOR USE IN MONITORING A POWER GENERATION SYSTEM

(71) Applicants: Venu Madhav Tadepalli, Alpharetta, GA (US); Blaine Madison Mucklow, Smyrna, GA (US); Ramon Juan San Andres, Duluth, GA (US); Atul Nigam, Johns Creek, GA (US); Prashant Kumar Sharma, Cumming, GA (US); Robert Michael Lewkovich, Smyrna, GA (US); Shitanshu Srivastava, Smyrna, GA (US); Deepti Bhutani, Alpharetta, GA (US)

(72) Inventors: Venu Madhav Tadepalli, Alpharetta, GA (US); Blaine Madison Mucklow, Smyrna, GA (US); Ramon Juan San Andres, Duluth, GA (US); Atul Nigam, Johns Creek, GA (US); Prashant Kumar Sharma, Cumming, GA (US); Robert Michael Lewkovich, Smyrna, GA (US); Shitanshu Srivastava, Smyrna, GA (US); Deepti Bhutani, Alpharetta, GA (US)

(21) Appl. No.: 13/224,939

(22) Filed: Sep. 2, 2011

(51) Int. Cl. G01R 31/08; G06F 19/00

(52) U.S. Cl. 702/59

(57) ABSTRACT

A monitoring system for use with a power generation system is provided. The monitoring system includes a plurality of sensors that include at least one sensor that is configured to detect an interruption of an electromagnetic field within the power generation system, wherein the interruption of the electromagnetic field corresponds to at least one fault within the power generation system. The monitoring system also includes a computing device that is coupled to the sensor. The computing device includes an interface configured to receive a signal representative of the interruption of the electromagnetic field. A processor is coupled to the interface and programmed to identify a location of the sensor to enable the identification of a location of the fault.

### BACKGROUND OF THE INVENTION

The field of the invention relates generally to power generation systems and, more particularly, to a monitoring system that monitors the operation of a power generation system.

At least some known power generation systems include one or more components that may become damaged and/or that may wear over time. For example, known power generation systems may include components such as, bearings, gears, and/or shafts that wear over time resulting in faults, such as a crack within the component, a disconnection of electrical wires, and/or a misalignment of the component. Continued operation with a worn component may cause additional damage to other components and/or may lead to a premature failure of the component or associated system. In addition, after a natural disaster, components of a power generation system may endure damage resulting in a fault. For example, a tree may fall on a power line causing a fault to the power line and/or an associated electrical circuit. Moreover, as a result of the fault, a circuit breaker protecting the electrical circuit may prevent the power generation system from operating until the power line and/or the circuit has been repaired.

To detect component damage within power generation systems and to provide an appropriate response solution, at least some known power generation systems are monitored with a monitoring system. At least some monitoring systems include computing modules and/or devices that can estimate a general location of a fault within the power generation system such that the fault may be restored. However, such modules and/or devices may be unable to determine the precise location of the fault. Accordingly, operators of a power generation system may still need to spend a considerable amount of time to locate the fault. As a result, the restoration of the power generation system may be substantially delayed.

### BRIEF DESCRIPTION OF THE INVENTION

In one embodiment, a monitoring system for use with a power generation system is provided. The monitoring system includes a plurality of sensors that include at least one sensor that is configured to detect an interruption of an electromagnetic field within the power generation system, wherein the interruption of the electromagnetic field corresponds to at least one fault within the power generation system. The monitoring system also includes a computing device that is coupled to the sensor. The computing device includes an interface configured to receive a signal representative of the interruption of the electromagnetic field. A processor is coupled to the interface and programmed to identify a location of the sensor to enable the identification of a location of the fault.

In another embodiment, a power generation system is provided. The power generation system includes at least one power line. The power generation system also includes a monitoring system that is coupled the power line. The monitoring system includes a plurality of sensors that are positioned proximate to the power line, wherein the sensors include at least one sensor that is configured to detect an interruption of an electromagnetic field within the power line. The interruption of the electromagnetic field corresponds to at least one fault within the power line. Moreover, the monitoring system includes a computing device that is coupled to the sensor. The computing device includes an interface that is configured to receive a signal representative of the interruption of the electromagnetic field. The computing device also includes a processor that is coupled to the interface and programmed to identify a location of the sensor to enable the identification of a location of the fault.

In yet another embodiment, a method for use in monitoring a power generation system is provided. An interruption of an electromagnetic field within the power generation system is detected via at least one sensor of a plurality of sensors, wherein the interruption of the electromagnetic field corresponds to at least one fault within the power generation system. A signal representative of the interruption of the electromagnetic field is transmitted to a computing device. Moreover, a location of the sensor is identified to enable the identification of a location of the fault.

### BRIEF DESCRIPTION OF THE DRAWINGS

FIG. 1 is a block diagram of an exemplary power generation system;

FIG. 2 is a block diagram of an exemplary monitoring system that may be used with the power generation system shown in FIG. 1; and

FIG. 3 is a flow chart of an exemplary method that may be used for monitoring the power generation system shown in FIG. 1.

### DETAILED DESCRIPTION OF THE INVENTION

The exemplary systems and methods described herein overcome at least some known disadvantages associated with at least some known power generation systems by providing a monitoring system that identifies a precise location of a fault within a power generation system. More specifically, the monitoring system described herein includes a plurality of sensors that include at least one sensor that detects an interruption of an electromagnetic field within the power generation system, wherein the interruption is associated with at least one fault within the power generation system. The monitoring system also includes a computing device that is coupled to the sensor and that includes an interface that receives a signal representative of the interruption of the electromagnetic field. A processor coupled to the interface is programmed to identify the precise location of the sensor to enable a location of the fault to be identified. By identifying the precise location of the fault, operators of the power generation system may be able to expeditiously restore the fault.

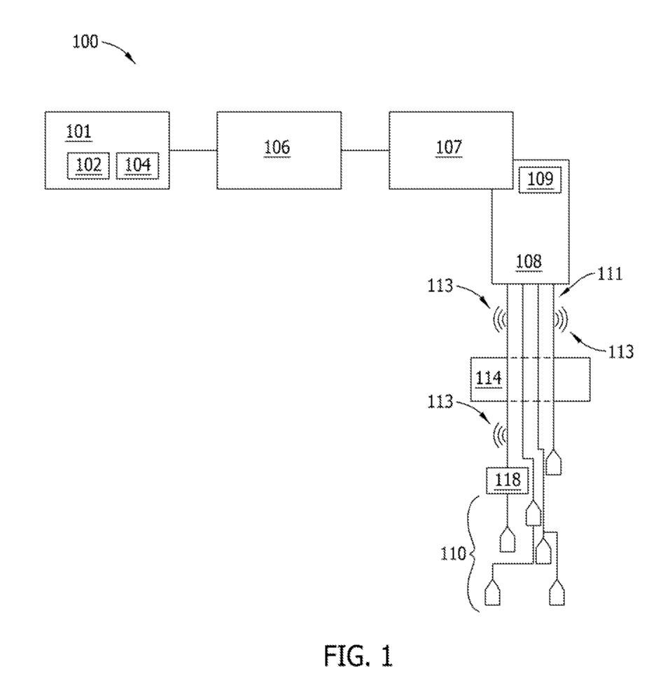

FIG. 1 illustrates an exemplary power generation system 100 that includes a machine 101. In the exemplary embodiment, machine 101 is a variable speed machine, such as a wind turbine, a hydroelectric turbine, a gas turbine, and/or any other machine that operates with a variable speed. Alternatively, machine 101 may be a synchronous speed machine. In the exemplary embodiment, machine 101 includes a rotating device 102, such as a rotor or other device. Moreover, in the exemplary embodiment, rotating device 102 rotates a drive shaft 104 that is coupled to a generator 106. In the exemplary embodiment, generator 106 is a doubly-fed induction generator that is coupled to a power distribution system 107. Alternatively, generator 106 may be any other type of generator that is coupled to any electrical system that enables power generation system 100 to function as described herein.

In the exemplary embodiment, power distribution system 107 includes an output section 108 that includes at least one electrical circuit 109 for providing electrical power to a plurality of buildings 110, via a plurality of power lines 111. In the exemplary embodiment, as electrical power is transmitted through power lines 111, an electromagnetic field 113 is generated propagated through power lines 111. Moreover, in the exemplary embodiment, power generation system 100 includes a monitoring system 114 that is coupled to power lines 111. Monitoring system 114 is able to detect at least one fault, such as fault 118 within power lines 111.

During operation, machine 101 generates mechanical rotational energy via rotating device 102 and drives generator 106. Generator 106 supplies electrical power to power distribution system 107. Moreover, in the exemplary embodiment, because of damage and/or vibration resulting from a natural disaster, for example, at least one fault, such as fault 118 within power line 111, may occur. In such an embodiment, fault 118 causes an interruption in a portion of electromagnetic field 113 and may cause a complete power shut down of system 100. As a result, buildings 110 are unable to receive power. In the exemplary embodiment, monitoring system 114, as described in more detail below, identifies the location of fault 118 such that an operator of power generation system 100 may repair fault 118 and power may be restored within system 100.

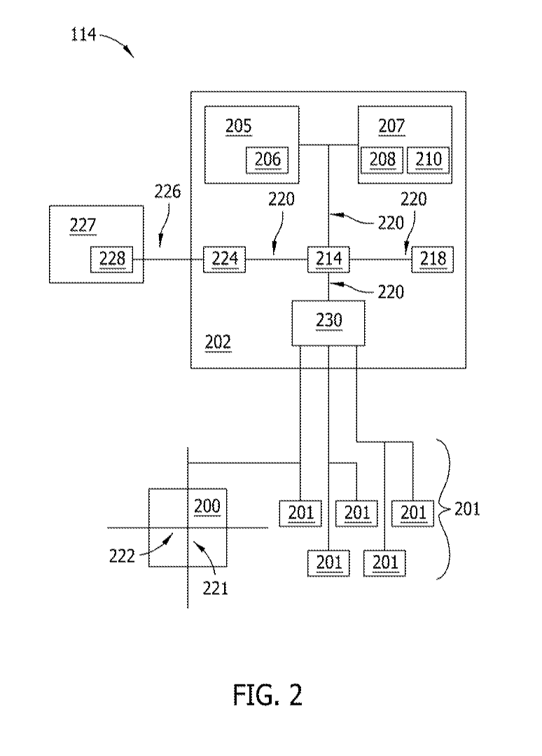

FIG. 2 is a block diagram of monitoring system 114. In the exemplary embodiment, monitoring system 114 includes a plurality of sensors 201, wherein at least one sensor 200 is positioned proximate to and/or along power lines 111 (shown in FIG. 1). In the exemplary embodiment, sensor 200 and sensors 201 are each electromagnetic field (EMF) sensors that can detect an interruption of electromagnetic field 113 (shown in FIG. 1). In the exemplary embodiment, the interruption of electromagnetic field 113 corresponds to a fault, such as fault 118 (shown in FIG. 1). For example, each fault, such as fault 118, may cause an interruption of electromagnetic field 113 at a portion of electromagnetic field 113 where the fault, such as fault 118, is located.

Monitoring system 114 also includes a computing device 202 that is coupled to sensor 200 and sensors 201 via data conduits 204. In the exemplary embodiment, computing device 202 includes a user interface 205 that is configured to receive at least one input from a user, such as an operator of power generation system 100 (shown in FIG. 1). In the exemplary embodiment, user interface 205 includes a keyboard 206 that enables a user to input pertinent information. Alternatively, user interface 205 may include, for example, a pointing device, a mouse, a stylus, a touch sensitive panel (e.g., a touch pad or a touch screen), a gyroscope, an accelerometer, a position detector, and/or an audio input interface (e.g., including a microphone).

Moreover, in the exemplary embodiment, computing device 202 includes a presentation interface 207 that presents information, such as input events and/or validation results, to the user. In the exemplary embodiment, presentation interface 207 includes a display adapter 208 that is coupled to at least one display device 210. More specifically, in the exemplary embodiment, display device 210 is a visual display device, such as a cathode ray tube (CRT), a liquid crystal display (LCD), an organic LED (OLED) display, and/or an “electronic ink” display. Alternatively, presentation interface 207 may include an audio output device (e.g., an audio adapter and/or a speaker) and/or a printer.

Computing device 202 also includes a processor 214 and a memory device 218. In the exemplary embodiment, processor 214 is coupled to user interface 205, presentation interface 207, and to memory device 218 via a system bus 220. In the exemplary embodiment, processor 214 communicates with the user, such as by prompting the user via presentation interface 207 and/or by receiving user inputs via user interface 205. Moreover, in the exemplary embodiment, processor 214 is programmed by encoding an operation using one or more executable instructions and providing the executable instructions in memory device 218. More specifically, in the exemplary embodiment, processor 214 is programmed to identify a location of at least one sensor, such as sensor 200 within power generation system 100. More specifically, in the exemplary embodiment, processor 214 is programmed to identify the location of sensor 200 by considering information, such as a plurality of locations of all sensors 201. In the exemplary embodiment, when processor 214 identifies the location of sensor 200, processor 214 is programmed to generate an output to a user. More specifically, in the exemplary embodiment, processor 214 is programmed to generate geographic coordinates regarding the location of sensor 200. In the exemplary embodiment, the geographic coordinates include a longitude coordinate 221 and a latitude coordinate 222 for the location of sensor 200.

The term “processor” refers generally to any programmable system including systems and microcontrollers, reduced instruction set circuits (RISC), application specific integrated circuits (ASIC), programmable logic circuits (PLC), and any other circuit or processor capable of executing the functions described herein. The above examples are exemplary only, and thus are not intended to limit in any way the definition and/or meaning of the term “processor.”

In the exemplary embodiment, memory device 218 includes one or more devices that enable information, such as executable instructions and/or other data, to be stored and retrieved. Moreover, in the exemplary embodiment, memory device 218 includes one or more computer readable media, such as, without limitation, dynamic random access memory (DRAM), static random access memory (SRAM), a solid state disk, and/or a hard disk. In the exemplary embodiment, memory device 218 stores, without limitation, application source code, application object code, configuration data, additional input events, application states, assertion statements, validation results, and/or any other type of data. More specifically, in the exemplary embodiment, memory device 218 stores input data received by the user via user interface 205 and/or information received from other components of monitoring system 114, such as sensor 200, and/or power generation system 100.

Computing device 202 also includes a network interface 224 that couples to a network 226 to facilitate communication with a data management system 227 that is included within monitoring system 114. In the exemplary embodiment, network 226 may include, but is not limited to only including, the Internet, a local area network (LAN), a wide area network (WAN), a wireless LAN (WLAN), a mesh network, and/or a virtual private network (VPN). More specifically, in the exemplary embodiment, data management system 227 includes a database 228 that includes information about power generation system 100, such as a plurality of locations, wherein each location corresponds to a location for each sensor 200 and 201. More specifically, in the exemplary embodiment, database 228 includes the location where each sensor 200 and 201 is positioned proximate to and/or along power lines 111.

Moreover, in the exemplary embodiment, data management system 227 communicates information from database 228 to computing device 202 via network 226. More specifically, in the exemplary embodiment, data management system 227 communicates with computing device 202 using a wireless communication means, such as radio frequency (RF), e.g., FM radio and/or digital audio broadcasting, an Institute of Electrical and Electronics Engineers (IEEE®) 802.11 standard (e.g., 802.11(g) or 802.11(n)), the Worldwide Interoperability for Microwave Access (WIMAX®) standard, a cellular phone technology (e.g., the Global Standard for Mobile communication (GSM)), a satellite communication link, and/or any other suitable communication means. WIMAX is a registered trademark of WiMax Forum, of Beaverton, Oreg. IEEE is a registered trademark of the Institute of Electrical and Electronics Engineers, Inc., of New York, N.Y. Alternatively, computing device 202 may communicate with data management system 227 using a wired network connection (e.g., Ethernet or an optical fiber).

Moreover, in the exemplary embodiment, computing device 202 includes a communication interface 230 that is coupled to processor 214 via system bus 220. Further, in the exemplary embodiment, communication interface 230 is coupled to sensor 200 and sensors 201 via conduits 204. Communication interface 230 is also configured to receive at least one signal from sensor 200 and sensors 201 via conduits 204.

During operation, because of damage and/or vibration resulting from a natural disaster, for example, at least one fault, such as fault 118 within power line 111, may occur. Each fault, such as fault 118, may cause an interruption in a portion of electromagnetic field 113 that results in a complete power shut down of system 100. As a result, buildings 110 (shown in FIG. 1) are unable to receive power from power generation system 100.

In the exemplary embodiment, monitoring system 114 identifies the location of fault 118 to enable it to be repaired and to enable power to be restored within system 100. More specifically, in the exemplary embodiment, sensor 200 of sensors 201 detects an interruption of electromagnetic field 113, as sensor 200 is positioned closest to fault 118. In the exemplary embodiment, because electrical power is transmitted via power lines 111, electromagnetic field 113 is generated and propagated through power lines 111. Sensors 201 detect the presence of electromagnetic field 113 throughout power lines 111. However, in the exemplary embodiment, there is an interruption of electromagnetic field 113 where fault 118 is located. In such an embodiment, sensor 200 detects the lack of the presence of electromagnetic field 113 (i.e., an interruption of electromagnetic 113).

When sensor 200 detects the interruption of electromagnetic field 113, sensor 200 transmits a signal representative of the interruption to computing device 202. Computing device 202 receives the signal via communication interface 230 and transmits the signal to processor 214. Processor 214 also transmits a signal via network 226 to data management system 227. In the exemplary embodiment, data management system 227 transmits information from database 228 to computing device 202 via network 226. More specifically, processor 214 receives information, such as a plurality of locations for sensors 200 and sensors 201. In the exemplary embodiment, each location corresponds to a location where each sensor 200 and 201 is positioned relative to power lines 111.

When processor 214 receives information from data management system 227, processor 214 identifies the location of each fault 118 by considering the location where each sensor 200 and 201 is positioned relative to power lines 111. More specifically, in the exemplary embodiment, processor 214 identifies a location of sensor 200 within power generation system 100 by considering each of the locations for each sensor 201. For example, processor 214 identifies which sensor of sensor 200 transmitted the signal representative of an interruption of electromagnetic field 113 to processor 214 and then processor 214 identifies the location based on the information received from data management system 227. Specifically, in the exemplary embodiment, processor 214 identifies that the signal was transmitted from sensor 200 and identifies the corresponding location of sensor 200 from the information received from data management system 227.

When processor 214 identifies the location of sensor 200, processor 214 generates an output than can be presented to a user. More specifically, processor 214 generates a geographic location of sensor 200 that includes a longitude coordinate 221 and a latitude coordinate 222 for the specific location of sensor 200 closest to fault 118. In the exemplary embodiment, the longitude coordinate 221 and latitude coordinate 222 are presented to a user via display device 210 of presentation interface 207. Since sensor 200 is positioned proximate to fault 118, the location of sensor 200 corresponds to the location of fault 118. As such, the user can identify the precise location of fault 118 and may be able to expeditiously restore fault 118.

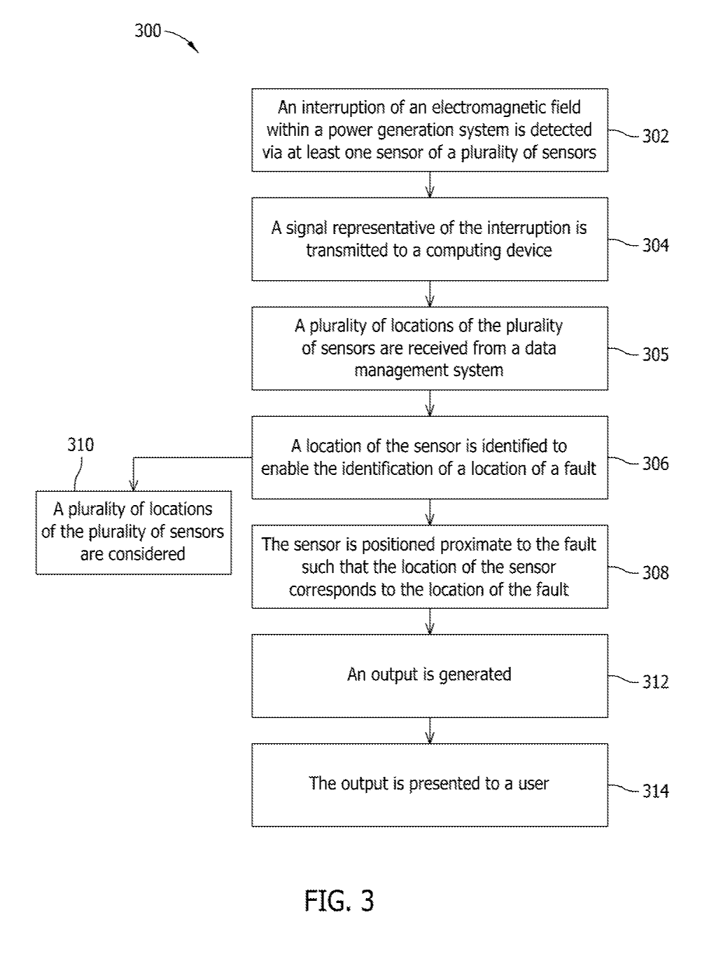

FIG. 3 is a flow chart of an exemplary method 300 that may be used for monitoring a power generation system, such as power generation system 100 (shown in FIG. 1), by using a monitoring system, such as monitoring system 114 (shown in FIGS. 1 and 2). An interruption of an electromagnetic field 113 (shown in FIG. 1) within power generation system 100 is detected 302 via at least one sensor 200 (shown in FIG. 2) of a plurality of sensors 201 (shown in FIG. 2), wherein the interruption of electromagnetic field 113 corresponds to at least one fault, such as fault 118 (shown in FIG. 1) within power generation system 100. A signal representative of the interruption of electromagnetic field 113 is transmitted 304 to a computing device 202 (shown in FIG. 2). A plurality of locations of sensors 200 and 201 are received 305 from a data management system 227 (shown in FIG. 2). A location of sensor 200 is identified 306 to enable the identification of a location of fault 118. More specifically, sensor 200 is positioned 308 proximate to fault 118 within power lines 111 (shown in FIG. 1) such that the location of sensor 200 corresponds to the location of fault 118.

A location of sensor 200 is identified 306 when a plurality of locations of sensors 200 and 201 are considered 310. An output that includes a longitude coordinate 221 (shown in FIG. 2) and a latitude coordinate 222 (shown in FIG. 2) for the location of sensor 200 is generated 312. The output is then presented 314 to a user such that fault 118 may be restored.

As compared to known power generation systems, the above described embodiments enable faults within power generation systems to be monitored and restored in a more accurate and efficient manner by providing a monitoring system that identifies a precise location of a fault within a power generation system. More specifically, the monitoring system described herein includes a plurality of sensors that include at least one sensor that detects an interruption of an electromagnetic field within the power generation system, wherein the interruption is associated with at least one fault within the power generation system. The monitoring system also includes a computing device that is coupled to the sensor and that includes an interface that receives a signal representative of the interruption of the electromagnetic field. A processor coupled to the interface is programmed to identify the precise location of the sensor to enable a location of the fault to be identified. By identifying the precise location of the fault, operators of the power generation system may be able to expeditiously restore the fault.

A technical effect of the systems and methods described herein includes at least one of: (a) detecting an interruption of an electromagnetic field within a power generation system via at least one sensor of a plurality of sensors, wherein the interruption of the electromagnetic field corresponds to at least one fault within the power generation system; (b) transmitting a signal representative of an interruption of an electromagnetic field to a computing device; and (c) identifying a location of at least one sensor of a plurality of sensors to enable the identification of a location of at least one fault.

Exemplary embodiments of the systems and methods for use in monitoring the operation of a power generation system are described above in detail. The systems and methods are not limited to the specific embodiments described herein, but rather, components of each system and/or steps of each method may be utilized independently and separately from other components and/or steps described herein. For example, each system may also be used in combination with other systems and methods, and is not limited to practice with only systems as described herein. Rather, the exemplary embodiment can be implemented and utilized in connection with many other applications.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A monitoring system for use with a power generation system, said monitoring system comprising:
a plurality of sensors comprising at least one sensor configured to detect an interruption of an electromagnetic field within the power generation system, wherein the interruption of the electromagnetic field corresponds to at least one fault within the power generation system; and
a computing device coupled to said at least one sensor, said computing device comprising:
an interface configured to receive a signal representative of the interruption of the electromagnetic field; and
a processor coupled to said interface and programmed to identify a location of said at least one sensor to enable the identification of a location of the at least one fault.

2. A monitoring system in accordance with claim 1, wherein said at least one sensor is positioned proximate to the at least one fault such that the location of said at least one sensor corresponds to the location of the at least one fault.

3. A monitoring system in accordance with claim 1, wherein said computing device further comprises a presentation interface coupled to said processor for selectively presenting an output of the location of the at least one fault to a user.

4. A monitoring system in accordance with claim 1, wherein said processor is further programmed to generate geographical coordinates for the location of said at least one sensor.

5. A monitoring system in accordance with claim 1, further comprising a data management system coupled to said computing device, said data management system comprises a database of a plurality of locations of each of said plurality of sensors.

6. A monitoring system in accordance with claim 4, wherein said processor is programmed to identify the location of said at least one sensor based on the plurality of locations of each of said plurality of sensors.

7. A monitoring system in accordance claim 4, wherein said computing device further comprises a network interface coupled to a network to enable said computing device to receive the plurality of locations of each of said plurality of sensors from said data management system.

8. A power generation system comprising:
at least one power line; and
a monitoring system coupled to said at least one power line, said monitoring system comprising:
a plurality of sensors positioned proximate to said at least one power line, wherein said plurality of sensors comprises at least one sensor configured to detect an interruption of an electromagnetic field within said at least one power line, the interruption of the electromagnetic field corresponds to at least one fault within said at least one power line; and
a computing device coupled to said at least one sensor, said computing device comprising:
an interface configured to receive a signal representative of the interruption of the electromagnetic field; and
a processor coupled to said interface and programmed to identify a location of said at least one sensor to enable the identification of a location of the at least one fault.

9. A power generation system in accordance with claim 8, wherein said at least one sensor is positioned proximate to the at least one fault such that the location of said at least one sensor corresponds to the location of the at least one fault.

10. A power generation system in accordance with claim 8, wherein said computing device further comprises a presentation interface coupled to said processor for selectively presenting an output of the location of the at least one fault to a user.

11. A power generation system in accordance with claim 8, wherein said processor is further programmed to generate geographical coordinates for the location of said at least one sensor.

12. A power generation system in accordance with claim 8, wherein said monitoring system further comprises a data management system coupled to said computing device, said data management system comprises a database of a plurality of locations of each of said plurality of sensors.

13. A power generation system in accordance with claim 12, wherein said processor is programmed to identify the location of said at least one sensor based on the plurality of locations of each of said plurality of sensors.

14. A power generation system in accordance with claim 8, wherein said computing device further comprises a network interface coupled to a network to enable said computing device to receive the plurality of locations of each of said plurality of sensors from said data management system.

15. A method for use in monitoring a power generation system, said method comprising:
detecting an interruption of an electromagnetic field within the power generation system via at least one sensor of a plurality of sensors, wherein the interruption of the electromagnetic field corresponds to at least one fault within the power generation system;
transmitting a signal representative of the interruption of the electromagnetic field to a computing device; and
identifying a location of the at least one sensor to enable the identification of a location of the at least one fault.

16. A method in accordance with claim 15, further comprising positioning the at least one sensor proximate to the at least one fault such that the location of the at least one sensor corresponds to the location of the at least one fault.

17. A method in accordance with claim 15, further comprising presenting an output of the location of the at least one fault to a user.

18. A method in accordance with claim 15, further comprising generating, via the computing device, geographical coordinates for the location of the at least one sensor.

19. A method in accordance with claim 15, further comprising receiving, via the computing device, a plurality of locations of the plurality of sensors from a data management system.

20. A method in accordance with claim 15, wherein identifying a location of the at least one sensor further comprises identifying a location of the at least one sensor based on a plurality of locations of the plurality of sensors.
